(19) United States
(12) Patent Application Publication
(10) Pub. No.: US 2007/0228401 A1
(43) Pub. Date: Oct. 4, 2007

(54) Semiconductor device

(76) Inventors: Osamu Machida, Niiza-shi (JP); Masataka Yanagihara, Niiza-shi (JP); Shinichi Iwakami, Niiza-shi (JP); Mio Suzuki, Niiza-shi (JP)

Correspondence Address: HOWARD & HOWARD ATTORNEYS, P.C., THE PINEHURST OFFICE CENTER, SUITE #101, 39400 WOODWARD AVENUE, BLOOMFIELD HILLS, MI, 48304-5151, US

(21) Appl. No.: 11/731,260

(22) Filed: Mar. 30, 2007

(30) Foreign Application Priority Data
Mar. 30, 2006 (JP) 2006-095926

(51) Int. Cl. H01L 33/00

(52) U.S. Cl. 257/96

(57) ABSTRACT

A semiconductor device having: a substrate; nitride-based compound semiconductor layers formed on one main surface of the substrate and made of a nitride-based compound semiconductor; a first electrode formed on the nitride-based compound semiconductor layers and having a Schottky junction with the nitride-based compound semiconductor layers; and a second electrode formed on the nitride-based compound semiconductor layers and subjected to low resistance contact with the nitride-based compound semiconductor layers, wherein the first electrode and substrate are electrically connected through a connection conductor.

### BACKGROUND OF THE INVENTION

1. Field of the Invention

The present invention relates to a semiconductor device, particularly to a semiconductor device using a nitride-based compound semiconductor.

2. Description of the Related Art

With regard to compound semiconductors, nitride, such as gallium nitride (GaN), has received attention as a semiconductor material with favorable characteristics of high temperature stability, large power output, and high operation frequency. For example, nitride-based compound semiconductors have a wider band gap than that of silicon semiconductors. Therefore, a nitride-based compound semiconductor is useful for a semiconductor device with stability in high temperature operations is required. In addition, the nitride-based compound semiconductor can increase electron mobility by forming a heterostructure such as gallium-aluminum nitride (AlGaN) and GaN. Therefore, a nitride-based compound semiconductor is useful for a semiconductor device with high-speed switching and high current is required. Furthermore, the nitride-based compound semiconductor has a high breakdown electrical field (dielectric breakdown electrical field strength). Therefore, a nitride-based compound semiconductor is preferably used when a semiconductor device capable of high voltage operation is required.

Such nitride-based compound semiconductors are used, for example, for Metal Semiconductor Field Effect Transistors (MSFET) and High Electron Mobility Transistors (HEMT). In addition, various suggestions have been made to enhance the performance of these semiconductor transistors.

For example, international patent publication No. 05/074019 bulletin discloses a semiconductor device comprising: a silicon-based substrate; a main semiconductor region including a nitride semiconductor layer formed on the silicon-based substrate; and a main electrode provided on the main semiconductor region, wherein by including a p-n junction in the silicon-based substrate, a high breakdown voltage semiconductor device can be provided.

However, as for the nitride-based compound semiconductor, there are a lot of deep level (trap) in a bulk crystal and a semiconductor surface. Therefore, there is a problem with the occurrence of so-called current collapse phenomenon because, for example, a carrier is captured in a trap within a crystal on a semiconductor substrate having a nitride-based compound semiconductor when reverse voltage is applied to the semiconductor device, or during the OFF state, the output current is decreased when forward voltage is applied or when switching to ON.

### SUMMARY OF THE INVENTION

Accordingly, the present invention aims to provide a semiconductor device capable with low current collapse.

The semiconductor device according to first aspect of the present invention comprises: a substrate; a nitride-based compound semiconductor layer formed on one main surface of the substrate and comprising a nitride-based compound semiconductor; a first electrode formed on the nitride-based compound semiconductor layer and having a Schottky junction with the nitride-based compound semiconductor layer; and a second electrode formed on the nitride-based compound semiconductor layer and subjected to low resistance contact with the nitride-based compound semiconductor layer, wherein the first electrode and the substrate are electrically connected through a connection conductor.

Additionally, a semiconductor device according to second aspect of the present invention comprises: a substrate; a nitride-based compound semiconductor layer formed on one main surface of the substrate and comprising a nitride-based compound semiconductor; a first electrode formed on the nitride-based compound semiconductor layer and having a Schottky junction with the nitride-based compound semiconductor layer; and a second electrode formed on the nitride-based compound semiconductor layer and subjected to low resistance contact with the nitride-based compound semiconductor layer, wherein the second electrode and the substrate are electrically connected through a connection conductor with an intervening diode.

Additionally, a semiconductor device according to the present invention comprises: a substrate; a nitride-based compound semiconductor layer formed on one main surface of the substrate and comprising a nitride-based compound semiconductor; a first electrode formed on the nitride-based compound semiconductor layer and having a Schottky junction with the nitride-based compound semiconductor layer; a second electrode formed on the nitride-based compound semiconductor layer and subjected to low resistance contact with the nitride-based compound semiconductor layer; and a voltage supply unit capable of applying electrical potential such that the electrical potential applied to the substrate or the nitride-based compound semiconductor layer is higher than the electrical potential applied to the first and the second substrate, wherein the substrate and the first electrode or the second electrode are electrically connected through a connection conductor with an intervening voltage supply unit.

Additionally, a semiconductor device according to the present invention comprises: a substrate; a nitride-based compound semiconductor layer formed on one main surface of the substrate and comprising a nitride-based compound semiconductor; a gate electrode formed on the nitride-based compound semiconductor layer and having a Schottky junction with the nitride-based compound semiconductor layer; a source electrode formed on the nitride-based compound semiconductor layer and subjected to low resistance contact with the nitride-based compound semiconductor layer; and a drain electrode formed on the nitride-based compound semiconductor layer and subjected to low resistance contact with the nitride-based compound semiconductor layer, wherein the source electrode and the substrate are electrically connected through a connection conductor.

Additionally, a semiconductor device according to the present invention comprises: a substrate; a nitride-based compound semiconductor layer formed on one main surface of the substrate and comprising a nitride-based compound semiconductor; a gate electrode formed on the nitride-based compound semiconductor layer and having a Schottky junction with the nitride-based compound semiconductor layer; a source electrode formed on the nitride-based compound semiconductor layer and subjected to low resistance contact with the nitride-based compound semiconductor layer; and a drain electrode formed on the nitride-based compound semiconductor layer and subjected to low resistance contact with the nitride-based compound semiconductor layer, wherein the gate electrode and the substrate are electrically connected through a connection conductor.

Additionally, a semiconductor device according to the present invention comprises: a substrate; a nitride-based compound semiconductor layer formed on one main surface of the substrate and comprising a nitride-based compound semiconductor; a gate electrode formed on the nitride-based compound semiconductor layer and having a Schottky junction with the nitride-based compound semiconductor layer; a source electrode formed on the nitride-based compound semiconductor layer and subjected to low resistance contact with the nitride-based compound semiconductor layer; and a drain electrode formed on the nitride-based compound semiconductor layer and subjected to low resistance contact with the nitride-based compound semiconductor layer, wherein the drain electrode and the substrate are electrically connected through a connection conductor with an intervening diode.

Additionally, a semiconductor device according to the present invention comprises: a substrate; a nitride-based compound semiconductor layer formed on one main surface of the substrate and comprising a nitride-based compound semiconductor; a gate electrode formed on the nitride-based compound semiconductor layer and having a Schottky junction with the nitride-based compound semiconductor layer; a source electrode formed on the nitride-based compound semiconductor layer and subjected to low resistance contact with the nitride-based compound semiconductor layer; and a drain electrode formed on the nitride-based compound semiconductor layer and subjected to low resistance contact with the nitride-based compound semiconductor layer, and a voltage supply unit capable of applying electrical potential such that the electrical potential applied to the substrate or the nitride-based compound semiconductor layer is higher than the electrical potential applied to the gate electrode, the source electrode, and the drain electrode, wherein the substrate and the drain electrode or the source electrode are electrically connected through a connection conductor.

Additionally, the nitride-based compound semiconductor layer may comprise a heterojunction.

Additionally, the substrate may be a conductive substrate, and a buffer layer may be provided between the substrate and the nitride-based compound semiconductor layer.

Additionally, it may further comprise a conductive frame provided on the other main surface of the substrate or on an exposed portion of the main surface of the substrate where the nitride-based compound semiconductor layer is not formed, wherein the substrate is electrically connected by connecting the frame and the connection conductor.

### BRIEF DESCRIPTION OF THE DRAWINGS

These objects and other objects and advantages of the present invention will become more apparent upon reading of the following detailed description and the accompanying drawings in which:

FIG. 1 is a sectional view showing the configuration of the semiconductor device of the first embodiment of the present invention;

FIG. 2 is a diagram viewing the Schottky barrier diode in FIG. 1 from overhead;

FIG. 3 is a sectional view showing the state in which reverse bias is applied to the Schottky diode in FIG. 1;

FIG. 4 is a sectional view showing the state of the Schottky diode in FIG. 1 when the forward bias shown is applied after which reverse bias is applied in FIG. 3;

FIG. 5 is a sectional view showing the configuration of the semiconductor device of the second embodiment of the present invention;

FIG. 6 is a sectional view showing the state in which reverse bias is applied to the Schottky diode in FIG. 5;

FIG. 7 is a sectional view showing the state of the Schottky diode in FIG. 5 when the forward bias shown is applied after which reverse bias is applied in FIG. 6;

FIG. 8 is a sectional view showing the configuration of the semiconductor device of the third embodiment of the present invention;

FIG. 9 is a diagram showing an overhead view of the HEMT in FIG. 8;

FIG. 10 is a sectional view showing the OFF state of the HEMT in FIG. 8;

FIG. 11 is the sectional view showing the OFF state of the HEMT in FIG. 8 switched to the ON state;

FIG. 12 is a sectional view showing the configuration of the semiconductor device of the fourth embodiment of the present invention;

FIG. 13 is a sectional view showing the OFF state of the HEMT in FIG. 12;

FIG. 14 is the sectional view showing the OFF state of the HEMT in FIG. 12 switched to the ON state;

FIG. 15 is the sectional view showing the OFF state of the semiconductor device of the other embodiments of the present invention switched to the ON state; and

FIG. 16 is a sectional view showing the configuration of the semiconductor device of the other embodiments of the present invention.

### DETAILED DESCRIPTION OF THE PREFERRED EMBODIMENTS

### First Embodiment

Now, the semiconductor device of the first embodiment of the present invention will be described assuming the semiconductor device including a Schottky barrier diode (SBD).

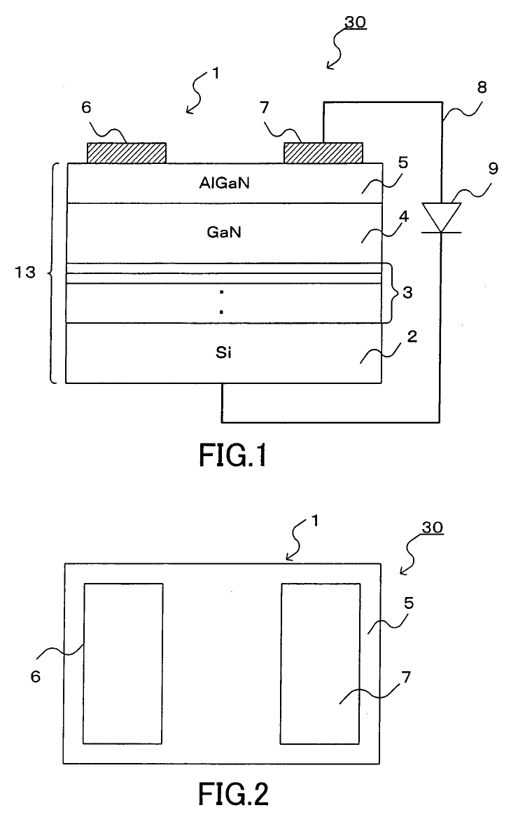

As shown in FIG. 1, the semiconductor device 30 of the present embodiment comprises a Schottky barrier diode 1 and en external diode 9 connected to the Schottky barrier diode 1 through a conductive conductor 8.

The Schottky barrier diode 1 of the present embodiment comprises a substrate 2, a buffer layer 3, an electron transit layer 4 and an electron supply layer 5 formed of nitride-based compound semiconductor layers, an anode electrode 6 serving as a first electrode, and a cathode electrode 7 serving as a second electrode.

The Schottky barrier diode 1 has, for example, a rectangular plane view shown in FIG. 2.

The substrate 2 is formed of a monocrystalline silicon substrate. A rear (back) electrode may be formed on a rear (under) surface of the substrate 2 so as to have low ohmic contact (resistive contact) with the substrate 2. In addition, a conductive support plate supporting the substrate 2 may be formed on the rear electrode on the rear surface of the substrate 2. In addition, a conductive junction layer may be formed between the rear electrode and the support plate to connect the rear electrode with the support plate.

The buffer layer 3 is formed on one main surface of the substrate 2. The buffer layer 3 transfers (shifts) the orientation of crystals of the substrate 2 to the electron transmit layer 4 so as to align the orientations of the crystal of the substrate 2 and the orientation of the crystal of the electron transmit layer 4.

The buffer layer 3 comprises a nitride-based compound semiconductor. The buffer layer 3 may, for example, comprise alternatively laminated layers of Al_{K}Ga_{1-K}N (0<K□1) and layers of GaN. The buffer layer 3 may be a known buffer layer such as a low temperature buffer layer comprising a single layer of Al_{K}Ga_{1-K}N, GaN, etc. However, the buffer layer 3 is preferably alternatively laminated layers rather than a single layer. The alternative lamination allows the buffer 3 to be thick and have a high quality. The thick high quality buffer layer 3 allows the electron transit layer 4 to be thick and thereby prevents warping and cracking on the electron transit layer 4 and improves crystal quality.

The electron transit layer 4 is formed on the buffer layer 3. The electron transit layer 4 acts as a channel layer. The electron transit layer 4 comprises gallium nitride-based compound semiconductor (GaN). The electron transit layer 4 is, for example, formed by laminating GaN layers onto the buffer layer 3 by metalorganic chemical vapor deposition (MOCVD).

The electron supply layer 5 is formed on the electron transit layer 4 and forms heterojunction therebetween. The electron supply layer 5 has the function to supply electrons to the electron transit layer 4. The electron supply layer 5, for example, comprises a nitride-based compound semiconductor, such as a gallium-aluminum nitride (AlGaN). The electron supply layer 5 is, for example, formed on the electron transit layer 4 by laminating AlGaN layers onto the electron transit layer 4 by metalorganic chemical vapor deposition (MOCVD).

The substrate 2, buffer layer 3, electron transit layer 4 and electron supply layer 5 form a semiconductor substrate 13.

A two-dimensional electron gas layer (2DEG layer) is generated at the periphery of the boundary between the electron supply layer 5 and the electron transit layer 4.

The anode electrode 6 is formed on the predetermined region of the electron supply layer 5 (on the main surface of the Schottky barrier diode 1) as shown in FIGS. 1 and 2. The anode electrode 6 is formed so as to have a Schottky junction with the electron supply layer 5. The anode electrode 6 comprises a nickel (Ni) film or a platinum (Pt) film, and a gold (Au) film formed on the Ni film or the Pt film. The anode electrode 6 is formed on the electron supply layer 5 by forming a Ni film (or a Pt film) and an Au film by sputtering, etc. and patterning formed laminated layers into a predetermined form by dry etching, etc.

The cathode electrode 7 is formed on the predetermined region of the electron supply layer 5 (on the main surface of the Schottky barrier diode 1) as shown in FIGS. 1 and 2. The cathode electrode 7 is formed so as to make low resistance contact (ohmic contact) with the electron supply layer 5. The cathode electrode 7 is formed on the electron supply layer 5 by, for example, forming a Ti film and an Al film by sputtering, etc. and patterning them into a predetermined form by dry etching, etc.

The connection conductor electrically connects the cathode electrode 7 and the substrate 2 of the Schottky barrier diode 1 through the external diode 9. The connection conductor 8 may be any conductor capable of electrically connecting the cathode electrode 7 and the external diode 9, and the substrate 2 and the external diode 9. For example, the connection conductor 8 comprises a wire made of a conductive material, or by providing an insulation film on the side surface of the Schottky barrier diode 1 and providing conductive patterns (conductive films such as metal patterns) thereon. The anode of the external diode 9 is electrically connected with the cathode electrode 7 of the Schottky barrier diode 1 through the connection conductor 8. The cathode of the external diode 9 is electrically connected with the substrate 2 of the Schottky barrier diode 1 through the connection conductor 8.

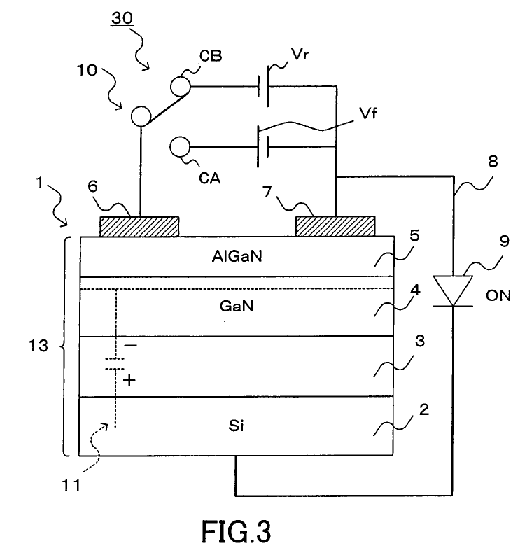

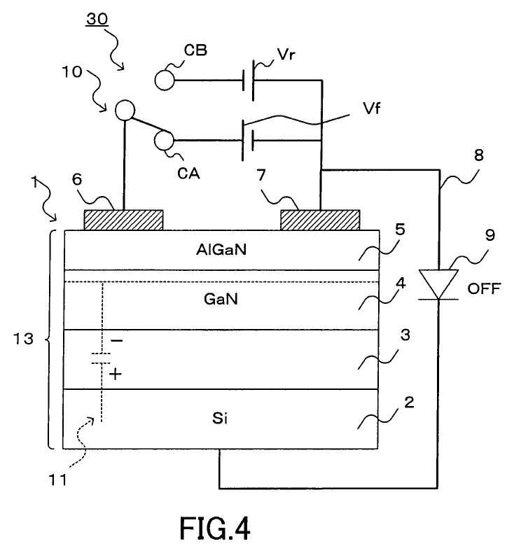

Next, the operations of the semiconductor device 30 constructed as above are described. FIG. 3 is a diagram illustrating the Schottky barrier diode 1 in the state of reverse bias being applied (the anode electrode 6 has lower electrical potential than the cathode electrode 7). FIG. 4 is a diagram illustrating the Schottky barrier diode 1 in the state of forward bias being applied after the application of reverse bias shown in FIG. 3.

Assume that, as shown in FIGS. 3 and 4, a switch 10 and batteries Vr, Vf are connected to the anode electrode 6 and the cathode electrode 7. The voltage of the battery Vr is several hundred (200 to 500 for example) volts, and applies a reverse bias to the Schottky barrier diode 1. The voltage of the battery Vf is several (2 to 5 for example) volts, and applies a forward bias to the Schottky barrier diode 1. When the switch 10 is connected to a terminal CB, the reverse bias of several hundred volts is applied to the Schottky barrier diode 1, and the external diode 9 is in a forward direction (ON). The external diode 9 is forwarded, the electrical potential of the cathode electrode 7 and the electrical potential of the substrate 2 will be approximately equal with each other. Since the ON voltage of the external diode 9 is mitigated compared to the voltage in reverse bias applied to the Schottky barrier diode 1 and the voltage of several hundred volts is applied between the anode electrode 6 and the substrate 2. The voltage also applied to a parasitic capacitor 11 formed between the substrate 2 and the electron supply layer 5. The substrate 2 side of the parasitic capacitor 11 becomes positively charged and the electron supply layer 5 side of the parasitic capacitor 11 becomes negatively charged. The parasitic capacitor 11 also becomes charged.

Then, as shown in FIG. 4, the switch 10 is connected from terminal CB to CA to change from a state in which several hundred volts of reverse bias is applied to the Schottky barrier diode 1 to a state in which several volts of forward bias is applied. When this occurs, the cathode electrode 7 has lower electrical potential than the anode electrodes 6 and the substrate 2 has higher electrical potential than the cathode electrode 7. Therefore, since the external diode 9 becomes reverse direction (OFF), the electrical charge of the parasitic capacitor 11 cannot be discharged through the external diode 9. Thus, the electrical charge accumulated in parasitic capacitor 11 generates an electrical field (carrier flow) that discharges electricity (self-discharge) in the high resistance crystal of the semiconductor substrate 13 comprising the Schottky barrier diode 1. That is, when the state of applying high voltage reverse bias is changed to forward bias, an electrical field is generated wherein an electrical potential (voltage supply unit) higher than that of the anode electrode 6 and the cathode electrode 7 is generated in the substrate 2.

The current collapse phenomenon can be considered as a phenomenon in which an electron is trapped in the crystals of the semiconductor substrate 13 by a reverse bias being applied to a semiconductor device and the resulting electrical field generated with the trapped electron decreases the two-dimensional electron gas generated at the boundary of the electron supply layer 5 and the electron transit layer 4. In the semiconductor device of this embodiment, because an electrical field higher than that of the cathode electrode 7 is generated on the substrate 2 and acts to cancel the electrical field generated by the electrons trapped in the crystals of the semiconductor substrate 13, the decrease of two-dimensional electron gas generated at the boundary surface of the electron supply layer 5 and the electron transit layer 4 is suppressed. As a result, occurrence of the current collapse phenomenon can be suppressed.

As described above, according to this embodiment, since the cathode electrode 7 and the anode side of the external diode 9, and the substrate 2 and the cathode side of the external diode 9 are electrically connected through the connection conductor 8, occurrence of the current collapse phenomenon can be suppressed. Moreover, the occurrence of the current collapse phenomenon can be suppressed by hardly changing the conventional design.

### Second Embodiment

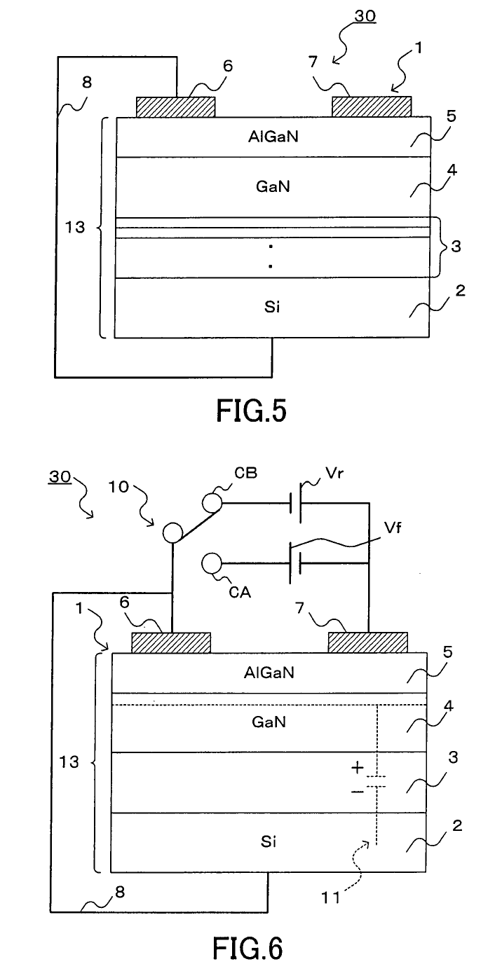

The second embodiment, as shown in FIG. 5, differs from the first embodiment in that the cathode electrode 7 and the substrate 2 are not electrically connected with an intervening external diode 9 there between, but the anode electrode 6 and the substrate 2 are electrically connected through the connection conductor 8. Now, in this embodiment, the differences from the first embodiment are mainly described. However, the same symbols correspond to the same members as in the first embodiment and the description is omitted.

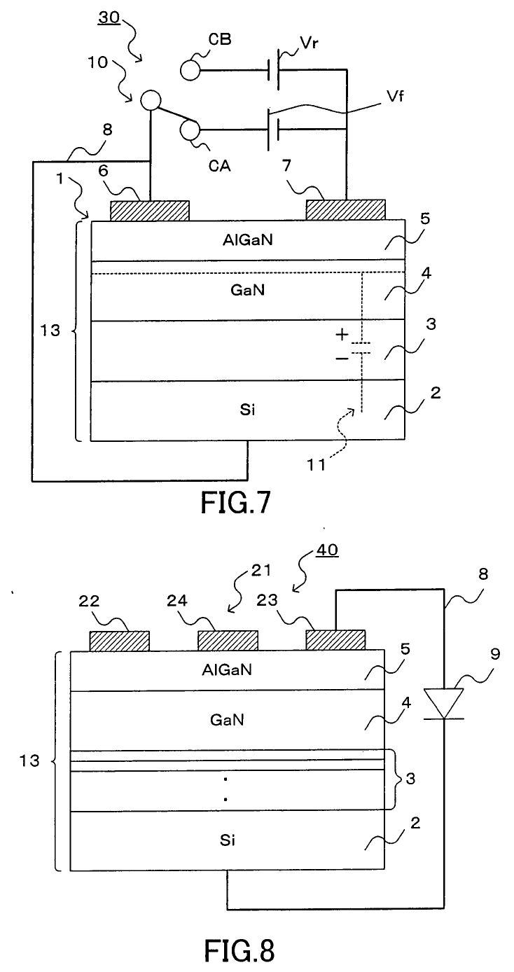

The actions and effects of the semiconductor device constructed in this manner will now be described. FIG. 6 is a diagram illustrating the Schottky diode 1 in the state of reverse bias being applied. FIG. 7 is a diagram illustrating the Schottky barrier diode 1 in the state of forward bias being applied as shown after which reverse bias is applied in FIG. 6.

As shown in FIG. 6, when a switch 10 connected to the anode electrode 6 is connected to CB (Vr: several hundred volts), reverse bias of several hundred volts (higher crest value than voltage crest value in forward bias) is applied to the Schottky barrier diode 1. However, since the anode electrode 6 and the substrate 2 are electrically connected through the connection conductor 8, several volts of voltage are applied between the cathode 7 and the substrate 2. Therefore, a parasitic capacitor (parasitic capacitance) 11 is generated in which the substrate 2 side becomes negatively charged and the electron supply layer 5 side becomes positively charged. The parasitic capacitor 11 also becomes charged.

Then, as shown in FIG. 7, the switch 10 is connected from CB to CA (Vf: several volts) to change from a state in which several hundred volts of reverse bias is applied to the Schottky barrier diode 1 to a state in which several volts of forward bias is applied. When this occurs, since the anode electrode 6 and the substrate 2 are electrically connected through the connection conductor 8, a voltage Vf (several volts) higher than the cathode electrode 7, which has the same electric potential as the anode electrode 6, is applied to the substrate 2. Thus, although the voltage of the substrate 2 and the cathode electrode 7 becomes Vf (several volts), a portion of the substrate 2 having higher electrical potential than the anode electrode 6 and the cathode electrode 7 is generated inside the semiconductor substrate 13 by the electrical charge accumulated in parasitic capacitor 11. As a result, the electrical charge accumulated in the parasitic capacitor 11 generates an electrical field (carrier flow) with a discharge characterized in that the high electrical potential generated by the high resistance inside the semiconductor substrate 13 approximates the electrical potential of the anode electrode 6 and the cathode electrode 7. That is, this electrical field can be likewise considered as the electrical field resulting from the electrical voltage generated at the anode electrode 6 and the cathode electrode 7 having higher electrical potential (current supply) than the substrate 2. This electrical field acts so as to cancel the electrical field generated by the trapped electron. Thus, the decrease of two-dimensional electron gas generated at the boundary of the electron supply layer 5 and the electron transit layer 4 is suppressed, and the occurrence of the current collapse phenomenon can be suppressed.

As described above, according to this embodiment, since the anode electrodes 6 and the substrate 2 are electrically connected through the connection conductor 8, the occurrence of the current collapse phenomenon can be suppressed. Moreover, the occurrence of the current collapse phenomenon can be suppressed by hardly changing the conventional design.

### Third Embodiment

In the third embodiment, the present invention is explained assuming a semiconductor device comprising a high electron mobility transistor (HEMT: High Electron Mobility Transistor) for example. However, in this embodiment, the same symbols are attached to the same members as the first embodiment and the description is omitted. Thus, in this embodiment, the differences from the first embodiment are mainly described.

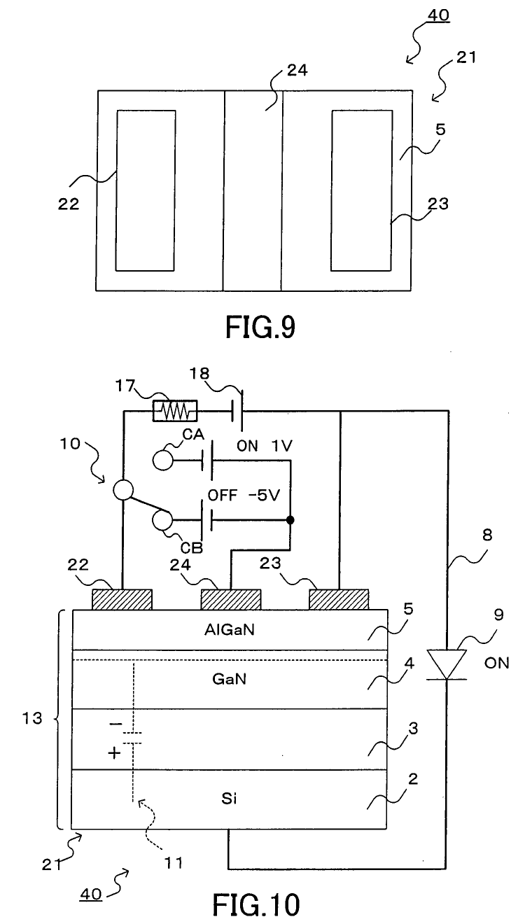

FIG. 8 is a diagram showing the configuration of a semiconductor device 40 of this embodiment. FIG. 9 is the diagram viewing HEMT in FIG. 8 from overhead, and it is a diagram showing an arrangement example of each electrode of HEMT.

As shown in FIG. 8 and FIG. 9, a gate electrode 24 as a first electrode, a drain electrode 23 as a second electrode, and a source electrode 22 as a third electrode are formed on the predetermined region on the electron supply layer 5 of a HEMT 21 (on the main substrate of the HEMT 21).

The source electrode 22 and the drain electrode 23 are, for example, formed so as to make low resistance contact (ohmic contact) with the electron supply layer 5. In this embodiment, the source electrode 22 and the drain electrode 23 are formed on the electron supply layer 5 by, for example, forming a Ti film and an Al film by sputtering, etc. and patterning into a predetermined form by dry etching, etc., on the electron supply layer 5.

The gate electrode 24 is formed on the predetermined region of the electron supply layer 5 so as to be sandwiched between the source electrode 22 and the drain electrode 23 and separated from them. However, the gate electrode 24 only needs to be formed such that it is separated from the source electrode 22 and the drain electrode 23 and able to control the current between the source electrode 22 and the drain electrode 23 with the voltage applied to the gate electrode 24. The gate 24 may, for example, be formed so as to surround either the source electrode 22 or the drain electrode 23. The gate electrode 24 is, for example, formed so as to have a Schottky junction with the electron supply layer 5. In this embodiment, the gate anode electrodes 24 is formed on the electron supply layer 5 comprising of a nickel (Ni) film or a platinum (Pt) film, and a gold (Au) film formed on the Ni film or the Pt film. The gate electrode 24 is formed on the electron supply layer 5 by, for example, forming a Ni film (or a Pt film) and an Au film by sputtering, etc. and patterning into a predetermined form by dry etching, etc., on the electron supply layer 5.

In addition, the HEMT 21 is electrically connected through the connection conductor 8, and the external diode 9 is intervened between the drain electrode 23 and the substrate 2. The connection conductor 8 may be any conductor capable of electrically connecting the drain electrode 23 and the outside diode 9, and the substrate 2 and the outside diode 9. For example, the connection conductor 8 is provided such as by a wire made of a conductive material, or by providing an insulation film on the side surface of the HEMT 21 and providing a pattern (conductive film) thereon. The external diode 9 is provided on the connection conductor 8 so that the anode side (one end of the connection conductor 8) is electrically connected with the drain electrode 23 and the cathode side (the other end of the connection conductor 8) is connected with the substrate 2.

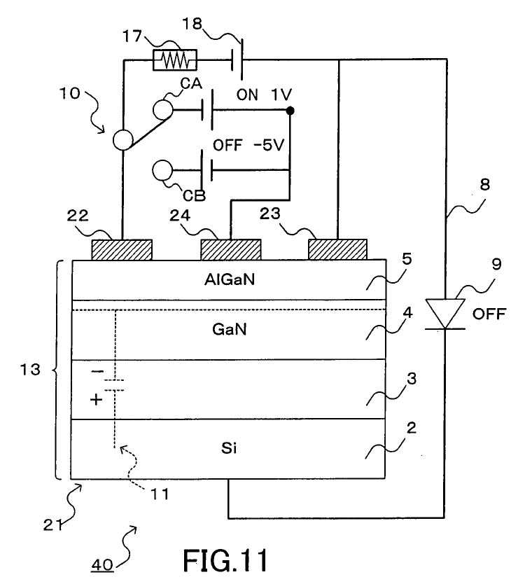

The actions and effects of the semiconductor device constructed in this manner will now be described. FIG. 10 is a diagram illustrating the HEMT 21 in the OFF state (the gate electrode 24 is OFF and drain electrode 23 has higher electrical potential than source electrode 22). HEMT 21 comprises a resistance 17 and a battery 18. FIG. 11 is a diagram illustrating the state in which the OFF state of the HEMT 21 shown in FIG. 10 is switched to the ON state.

As shown in FIG. 10, when the switch 10 connected to the source electrode 22 is connected to CB (the voltage to OFF the gate electrode 24 of the HEMT 21, e.g., −5 V), as much as several hundred volts of voltage is applied to the HEMT 21 (between the drain electrode 23 and the source electrode 22, and between the drain electrode 23 and the gate electrode 24). Wherein, since the external diode 9 is a forward direction (ON), the electrical potential of the drain electrode 23 and the electrical potential of the substrate 2 will be approximately equal electrical potential. Thus, as shown in FIG. 10, the voltage of several hundred volts is applied between the source electrode 22 and the substrate 2, and a parasitic capacitor (parasitic capacitance) 11 is generated in which the substrate 2 side becomes positively charged and the electron supply layer 5 side becomes negatively charged. This parasitic capacitor 11 also becomes charged.

Then, as shown in FIG. 11, when the switch 10 is switched from CB to CA, the HEMT 21 turns ON and the current is passed, the state of the electrical potential of the source electrode 22 is switched from the state of several hundred volts lower than that of the drain electrode 23 to several volts or below. Wherein, since the current is passed between the drain electrode 23 and the source electrode 22 (between drain and source) of the HEMT 21, the voltage applied between the source and the source will be the voltage dropped by the resistance (ON resistance between the drain and the source) generated by passing of current. The electrical potential of the substrate 2 is higher than that of the drain electrode 23 and thus the external diode 9 becomes reverse direction (OFF). Therefore, the electrical charge of the parasitic capacitor 11 cannot be discharged through the external diode 9. Thus, the electrical charge accumulated in parasitic capacitor 11 generates an electrical field (carrier flow) that discharges electricity (self-discharge) from the high resistance crystal of the semiconductor substrate 13 comprising the HEMT 21. That is, when the state of applying high voltage reverse bias is changed to forward bias, an electrical field is generated in the semiconductor substrate 13 because the electrical potential (voltage supply unit) which is higher than that of the source electrode 22, drain electrode 23, and the gate electrode 24 in the substrate 2 is generated. This electrical field acts to cancel the electrical field generated by the trapped electron. Thus, the decrease of the two-dimensional electron gas generated at the boundary of the electron supply layer 5 and the electron transit layer 4 is suppressed, and the occurrence of the current collapse phenomenon can be suppressed.

As described above, according to this embodiment, since the drain electrode 23 and the substrate 2 are electrically connected through the connection conductor 8, the occurrence of the current collapse phenomenon can be suppressed. Moreover, the occurrence of the current collapse phenomenon can be suppressed by hardly changing the conventional design.

### Fourth Embodiment

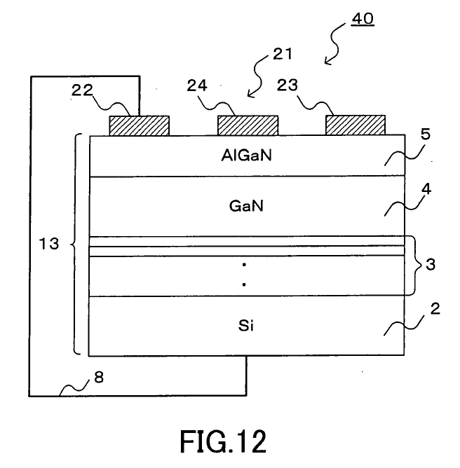

In the forth embodiment, as shown in FIG. 12, it is different from the third embodiment in that the drain electrode 23 and the substrate 2 are not electrically connected through the connection conductor 8 by the intervening external diode 9, but the source electrode 22 and the substrate 2 are electrically connected through the connection conductor 8. Now, in this embodiment, the differences from the third embodiment are mainly described. However, the same symbols are attached to the same members as in the third embodiment and the description is omitted.

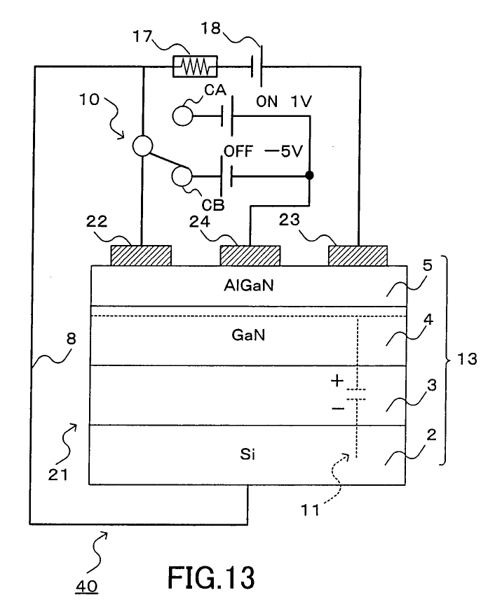

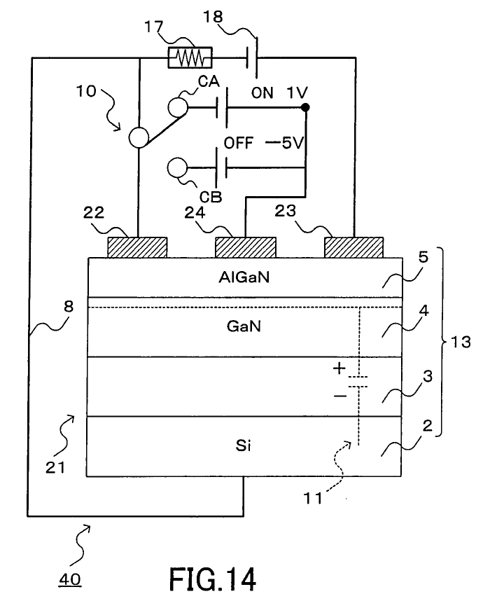

The actions and effects of the semiconductor device constructed in this manner will now be described. FIG. 13 is a diagram illustrating the HEMT 21 in the OFF state. FIG. 14 is a diagram illustrating the state in which the OFF state of the HEMT 21 shown in FIG. 13 is switched to the ON state.

As shown in FIG. 13, when the switch 10 connected to the source electrode 22 is connected to B (voltage switched to OFF on the gate electrode 24, e.g., −5 V), several hundred volts of voltage is applied between the drain electrode 23 and the source electrode 22, and between the drain electrode 23 and the gate electrode 24 of the HEMT 21. The source electrode 22 and the substrate 2 are electrically connected through the connection conductor 8. Thus, a parasitic capacitor (parasitic capacitance) 11 in which the substrate 2 side becomes negatively charged and the electron transit layer 4 side becomes positively charged is generated between the drain electrode 23 and the substrate 2. The parasitic capacitor 11 also becomes charged.

Then, as shown in FIG. 14, when the switch 10 is switched to CA (voltage ON to the gate electrode 24 of the HEMT 21, e.g., 1 V is applied), the HEMT 21 turns ON and current is passed, and the state in which voltage of several hundred volts is applied between the drain electrode 23 and the source electrode 22 is switched to the state in which voltage of several volts or below is applied as in the third embodiment. Since current is passed between the drain electrode 23 and the source electrode 22 (between the drain and source) of the HEMT 21, the voltage applied between the drain and the source will be decreased by the resistance (ON resistance between the drain and the source) generated by passing the current. When this occurs, since the source electrode 22 and the substrate 2 are electrically connected through the connection conductor 8, when the HEMT 21 turns ON, the voltage of the source electrode 22 is applied to the substrate 2 and a voltage several volts higher than the drain electrode 23 is applied. Thus, although the voltage of the substrate 2 and the drain electrode 23 becomes several volts, a portion of the substrate 2 having higher electrical potential than the source electrode 22, the drain electrode 23, and the gate electrode 24 is generated inside the semiconductor substrate 13 by the electrical charge accumulated in parasitic capacitor 11. As a result, the electrical charge accumulated in the parasitic capacitor 11 generates an electrical field (carrier flow) with a discharge characterized in that the high electrical potential generated by the high resistance inside the semiconductor substrate 13 approximates the electrical potential of the source electrode 22, the drain electrode 23, and the gate electrode 24. That is, the electrical field can be likewise considered as the electrical field resulting from a higher electrical potential (voltage supply) being generated at the source electrode 22, the drain electrode 23, and the gate electrode 24 than at the substrate 2. This electrical field also acts to cancel the electrical field generated by the trapped electron. Thus, the decrease of the two-dimensional electron gas generated at the boundary of the electron supply layer 5 and the electron transit layer 4 is suppressed, and thereby, the occurrence of the current collapse phenomenon can be suppressed.

As described above, according to this embodiment, since the source electrodes 22 and the substrate 2 are electrically connected through the connection conductor 8, the occurrence of the current collapse phenomenon can be suppressed. Moreover, the occurrence of the current collapse phenomenon can be suppressed by hardly changing the conventional design.

However, the above embodiments are not intended as limitations, and various modifications and applications may be made to the present invention. Now, other embodiments to which the present invention is applicable will be described.

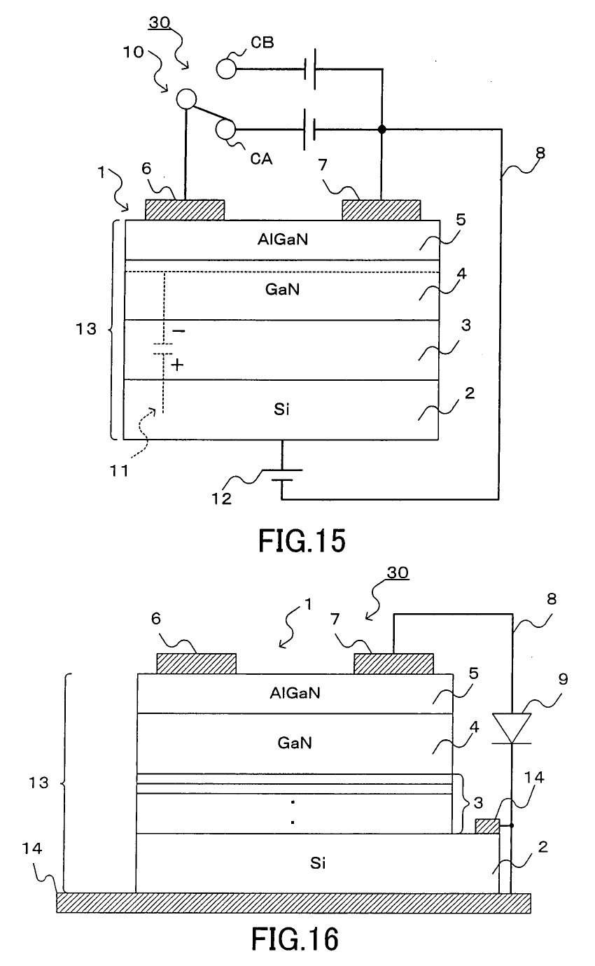

For example, in the first and third embodiments, the present invention was described assuming that the external diode 9 intervenes with the connection conductor 8, for example. However, for example, in the first embodiment, as shown in FIG. 15, a voltage supply unit 12 may intervene with the connection conductor 8 instead of the external diode 9, such that the rear surface of the substrate 2 gains a state of higher electronic potential than the cathode electrode 7 (drain electrode 23 in the case of the third embodiment). In this case again, when it is switched from the OFF state (CB) to the ON state (CA), an electrical field is generated in the substrate 2 due to the higher electrical potential (voltage supply unit 12) than that of the cathode electrode 7 (drain electrode 23 in the case of the third embodiment). This electrical field acts to cancel the electrical field generated by the trapped electron. Thus, the decrease of the two-dimensional electron gas generated at the boundary of the electron supply layer 5 and the electron transit layer 4 is suppressed, and thereby, the occurrence of the current collapse phenomenon can be suppressed. However, although FIG. 15 shows an example in which the connection conductor 8 is provided so that the electronic potential of the substrate 2 becomes higher compared to the cathode electrode 7, the voltage supply unit 12 and the connection conductor 8 may be provided between the anode electrode 6 and the substrate 2 such that the electrical potential of the substrate 2 becomes higher compared to the anode electrode 6.

In the third and forth embodiments, although the present invention was described assuming a semiconductor device 40 comprising an HEMT 21 as an example, it may also be, for example, a Metal Semiconductor Filed Effect Transistor (MSFET). In addition, although in the fourth embodiment, the present invention was described assuming a case in which, as one example, the source electrode 22 and the substrate 2 are electrically connected, as another example, the gate electrode 24 and the substrate 2 may be electrically connected. In such case as well, as in the fourth embodiment, the occurrence of the current collapse phenomenon can be suppressed.

In the above embodiments, although the present invention was described assuming a case in which the other end of the connection conductor 8 is connected to the rear surface of the substrate 2, for example, it is only required that the connection conductor 8 and the substrate 2 are electrically connected. For example, as shown in FIG. 16, a frame 14 may be provided on the rear surface of the substrate 2 and the other end of the connection conductor 8 may be connected to the frame 14. In addition, an exposed portion where the buffer layer 3 is not formed on the top surface of the substrate 2 may be provided and the one end of the connection conductor 8 may be connected to this exposed portion of the substrate 2.

Further, a noise filter comprising a coil, a resistor, a capacitor, etc. may be provided to the connection conductor 8. In this case, a decrease in the suppressive effect on the current collapse phenomenon may occur due to noise passed from the substrate 2 to the electron supply layer 5 through the anode electrode 6. A noise filter such as a filter may be used wherein a resistor and a capacitor are constructed serially or in parallel to reduce low frequency noise.

In the above embodiment, the present invention was described assuming a case in which the electrodes (anode electrode 6, cathode electrode 7, source electrode 22, drain electrode 23) formed on the electron supply layer 5 are connected to the substrate 2 through the connection conductor 8 or the connection conductor 8 with an intervening external diode 9, for example. However, for example, the external diode 9 or the like may be formed on the same substrate (substrate 2) integrally with the Schottky barrier diode 1 or the HEMT 21.

Although, in the above embodiment, the present invention was described assuming a case in which the buffer layer 3 is formed on the substrate 2, for example, the electron transit layer 4 may be formed on the substrate 2 without forming a buffer layer 3.

Although, in the above embodiment, the present invention was described assuming a case in which the substrate 2 is formed from single crystal silicon, for example, the substrate 2 also may be, for example, formed from an insulating substrate of sapphire (Al₂O₃) or silicon carbide (SiC) or a conductive substrate other than GaN and silicon. In addition, in the above embodiment, the external diode 9 may comprise a Schottky diode, a PN diode, a PIN diode, etc.

However, in the semiconductor device, a GaN layer may be further provided on the electron supply layer 5 (AlGaN layer) and a SiN protective film layer may be formed on the GaN layer. With such configuration, suppression of the current collapse can be further achieved. Employing this configuration, for example, in the semiconductor device related to the third embodiment, the following configuration can be assumed for the semiconductor device according to one embodiment of the present invention: The electron transit layer 4 (GaN layer) is provided on the substrate 2 through the buffer layer 3. The electron supply layer 5 (AlGaN layer) is provided on the electron transit layer 4 (GaN layer). The GaN layer is provided on the electron supply layer 5 (AlGaN layer). The SiN protective film layer is formed on the GaN layer. The gate electrode 24 comprising a Schottky diode connected to the GaN layer through the SiN protective film layer is provided. The source electrode 22 with an ohmic connection to the GaN layer through the SiN protective film layer is provided. And, the drain electrode 23 with an ohmic connection to the GaN layer through the SiN protective film layer is provided.

The reason for employing such configuration to achieve further suppression of the current collapse may be considered as follows. That is, one of the reasons for the occurrence of current collapse is assumed to be surface defect due to nitrogen depletion on the surface of the AlGaN layer upon completion of crystal growth or during a device process. Therefore, it is assumed that the surface of the AlGaN layer may be stabilized by further providing a GaN layer on the AlGaN layer and forming a SiN protective layer on the GaN layer. The current collapse phenomenon may be further achieved by the combination of surface stabilization of the AlGaN layer and the canceling action by the parasitic capacitor on the electrical field generated by the crystal trapped electrons.

Various embodiments and changes may be made thereunto without departing from the broad spirit and scope of the invention. The above-described embodiments are intended to illustrate the present invention, not to limit the scope of the present invention. The scope of the present invention is shown by the attached claims rather than the embodiments. Various modifications made within the meaning of an equivalent of the claims of the invention and within the claims are to be regarded to be in the scope of the present invention.

This application is based on Japanese Patent Application No. 2006-095926 filed on Mar. 30, 2006 and including specification, claims, drawings and summary. The disclosure of the above Japanese Patent Application is incorporated herein by reference in its entirety.

What is claimed is:

1. A semiconductor device comprising:
a substrate;
a nitride-based compound semiconductor layer formed on one main surface of the substrate and comprising a nitride-based compound semiconductor;
a first electrode formed on the nitride-based compound semiconductor layer and having a Schottky junction with said nitride-based compound semiconductor layer; and
a second electrode formed on the nitride-based compound semiconductor layer and subjected to low resistance contact with said nitride-based compound semiconductor layer, wherein the first electrode and the substrate are electrically connected through a connection conductor.

2. A semiconductor device comprising:
a substrate;
a nitride-based compound semiconductor layer formed on one main surface of the substrate and comprising a nitride-based compound semiconductor;
a first electrode formed on the nitride-based compound semiconductor layer and having a Schottky junction with said nitride-based compound semiconductor layer; and
a second electrode formed on the nitride-based compound semiconductor layer and subjected to low resistance contact with said nitride-based compound semiconductor layer, wherein the second electrode and the substrate are electrically connected through a connection conductor with an intervening diode.

3. A semiconductor device comprising:
a substrate;
a nitride-based compound semiconductor layer formed on one main surface of the substrate and comprising a nitride-based compound semiconductor;
a first electrode formed on the nitride-based compound semiconductor layer and having a Schottky junction with said nitride-based compound semiconductor layer;
a second electrode formed on the nitride-based compound semiconductor layer and subjected to low resistance contact with said nitride-based compound semiconductor layer; and
a voltage supply unit capable of applying electrical potential such that the electrical potential applied to the substrate or the nitride-based compound semiconductor layer is higher than the electrical potential applied to the first and the second electrode, and wherein the substrate and the first electrode or the second electrode are electrically connected through a connection conductor with an intervening voltage supply unit.

4. A semiconductor device comprising:
a substrate;
a nitride-based compound semiconductor layer formed on one main surface of the substrate and comprising a nitride-based compound semiconductor;
a gate electrode formed on the nitride-based compound semiconductor layer and having a Schottky junction with said nitride-based compound semiconductor layer;
a source electrode formed on the nitride-based compound semiconductor layer and subjected to low resistance contact with said nitride-based compound semiconductor layer; and
a drain electrode formed on the nitride-based compound semiconductor layer and subjected to low resistance contact with said nitride-based compound semiconductor layer, wherein the source electrode and the substrate are electrically connected through a connection conductor.

5. A semiconductor device comprising:
a substrate;
a nitride-based compound semiconductor layer formed on one main surface of the substrate and comprising a nitride-based compound semiconductor;
a gate electrode formed on the nitride-based compound semiconductor layer and having a Schottky junction with said nitride-based compound semiconductor layer;
a source electrode formed on the nitride-based compound semiconductor layer and subjected to low resistance contact with said nitride-based compound semiconductor layer; and
a drain electrode formed on the nitride-based compound semiconductor layer and subjected to low resistance contact with said nitride-based compound semiconductor layer, wherein the gate electrode and the substrate are electrically connected through a connection conductor.

6. A semiconductor device comprising:
a substrate;
a nitride-based compound semiconductor layer formed on one main surface of the substrate and comprising a nitride-based compound semiconductor;
a gate electrode formed on the nitride-based compound semiconductor layer and having a Schottky junction with said nitride-based compound semiconductor layer;
a source electrode formed on the nitride-based compound semiconductor layer and subjected to low resistance contact with said nitride-based compound semiconductor layer; and
a drain electrode formed on the nitride-based compound semiconductor layer and subjected to low resistance contact with said nitride-based compound semiconductor layer, wherein the drain electrode and the substrate are electrically connected through a connection conductor with an intervening diode.

7. A semiconductor device comprising:
a substrate;
a nitride-based compound semiconductor layer formed on one main surface of the substrate and comprising a nitride-based compound semiconductor;
a gate electrode formed on the nitride-based compound semiconductor layer and having a Schottky junction with said nitride-based compound semiconductor layer;
a source electrode formed on the nitride-based compound semiconductor layer and subjected to low resistance contact with said nitride-based compound semiconductor layer;
a drain electrode formed on the nitride-based compound semiconductor layer and subjected to low resistance contact with said nitride-based compound semiconductor layer, and
a voltage supply unit capable of applying electrical potential such that the electrical potential applied to the substrate or the nitride-based compound semiconductor layer is higher than the electrical potential applied to the gate electrode, the source electrode, and the drain electrode, wherein the substrate and the drain electrode or the source electrode are electrically connected through a connection conductor with the intervening voltage supply unit.

8. The semiconductor device according to claim 1, wherein the nitride-based compound semiconductor layer comprises laminated layers having a heterojunction.

9. The semiconductor device according to claim 2, wherein the nitride-based compound semiconductor layer comprises laminated layers having a heterojunction.

10. The semiconductor device according to claim 3, wherein the nitride-based compound semiconductor layer comprises laminated layers having a heterojunction.

11. The semiconductor device according to claim 1, further comprising a buffer layer provided between the substrate and the nitride-based compound semiconductor layer; wherein the substrate is formed of semiconductor.

12. The semiconductor device according to claim 2, further comprising a buffer layer provided between the substrate and the nitride-based compound semiconductor layer; wherein the substrate is formed of semiconductor.

13. The semiconductor device according to claim 3, further comprising a buffer layer provided between the substrate and the nitride-based compound semiconductor layer; wherein the substrate is formed of semiconductor.

14. The semiconductor device according to claim 1, further comprising a conductive frame provided on the substrate, wherein the substrate is electrically connected to the connection conductor by connecting the frame and the connection conductor.

15. The semiconductor device according to claim 2, further comprising a conductive frame provided on the substrate, wherein the substrate is electrically connected to the connection conductor by connecting the frame and the connection conductor.

16. The semiconductor device according to claim 3, further comprising a conductive frame provided on the substrate, wherein the substrate is electrically connected to the connection conductor by connecting the frame and the connection conductor.

17. A semiconductor device comprising:
a substrate;
a nitride-based compound semiconductor layer formed on a surface of the substrate;
a first electrode formed on the nitride-based compound semiconductor layer and having a Schottky junction with said nitride-based compound semiconductor layer;
a second electrode formed on the nitride-based compound semiconductor layer and having a resistance contact with said nitride-based compound semiconductor layer; and
means for suppressing the current collapses.

18. A semiconductor device comprising:
a substrate;
a nitride-based compound semiconductor layer formed on a surface of the substrate;
a first electrode formed on the nitride-based compound semiconductor layer and having a Schottky junction with said nitride-based compound semiconductor layer;
a second electrode formed on the nitride-based compound semiconductor layer and having a resistance contact with said nitride-based compound semiconductor layer; and
means for generating a parasitic capacitor between the substrate and the nitride-based compound semiconductor layer and controlling the parasitic capacitor.
